(19) United States
(12) Patent Application Publication
(10) Pub. No.: US 2025/0246455 A1
(43) Pub. Date: Jul. 31, 2025

(54) CHIP EJECTING APPARATUS AND METHOD FOR FABRICATING SEMICONDUCTOR DEVICE USING THE SAME

(71) Applicant: SAMSUNG ELECTRONICS CO., LTD., Suwon-si (KR)

(72) Inventor: Jung Sik Lee, Suwon-si (KR)

(21) Appl. No.: 18/785,328

(22) Filed: Jul. 26, 2024

(30) Foreign Application Priority Data
Jan. 31, 2024 (KR) 10-2024-0014921

(51) Int. Cl. H01L 21/67; H01L 21/78

(52) U.S. Cl. CPC H01L 21/67132; H01L 21/78

(57) ABSTRACT

An apparatus for ejecting a chip is provided. The apparatus for ejecting the chip includes a body formed with a plurality of vacuum holes, and an ejecting bar provided in the body and driven to ascend and descend along a first direction, wherein the ejecting bar is driven upward along the first direction to push up a target semiconductor chip attached onto a mount tape so that a collet device adsorbs and picks up the target semiconductor chip, and the body sucks the air through the plurality of vacuum holes to adsorb and fix semiconductor chips downward along the first direction, which are attached onto the mount tape by being disposed to be adjacent to the mount tape and the target semiconductor chip.

### CROSS-REFERENCE TO RELATED APPLICATION

This application claims priority to Korean Patent Application No. 10-2024-0014921, filed on Jan. 31, 2024, in the Korean Intellectual Property Office under 35 U.S.C. 119, the content of which in its entirety is herein incorporated by reference.

### BACKGROUND

Semiconductor devices may be formed on a wafer by repeatedly performing a series of fabricating processes. The wafer on which the semiconductor devices are formed may be divided into a plurality of chips (dies) through a dicing process, and each of the divided chips may be bonded onto a substrate (e.g., a printed circuit board (PCB)) through a die attaching process.

Equipment for performing the die attaching process may include an ejecting device that separates a chip from a wafer for which a dicing process has been performed, a collet device that picks up the separated chip, and a bonding device that bonds the picked-up chip onto a substrate.

Meanwhile, in order to prevent chips from being detached in the dicing process, a mount tape attached to a back surface of a wafer may be used. Each individualized chip may be separated from the mount tape by the ejecting device.

This ejecting device pushes up the semiconductor chips attached to the mount tape below the mount tape by a needle or a pin to separate them from the mount tape, so that they are picked up by an adsorption device such as a collet device.

However, during the die (chip) pickup process described above, the semiconductor chips may be stressed by the needle or the pin in the process of being separated from the mount tape.

In particular, the stress may be applied to a miniaturized and thinned semiconductor chip more severely, whereby damage such as crack may be caused to the semiconductor chip.

### BRIEF SUMMARY

The present disclosure provides a chip ejecting apparatus that minimizes stress that can be applied to a semiconductor chip to suppress damage to the semiconductor chip when the semiconductor chip is picked up by being separated from a mount tape during a die attaching process, and a method for fabricating a semiconductor device using the chip ejecting apparatus.

According to some implementations of the present disclosure, there is provided a chip ejecting apparatus, comprising a body formed with a plurality of vacuum holes; and an ejecting bar provided in the body and driven to ascend and descend along a first direction, wherein the ejecting bar is driven upward along the first direction to push up a target semiconductor chip attached onto a mount tape so that a collet device adsorbs and picks up the target semiconductor chip, and the body sucks the air through the plurality of vacuum holes to adsorb and fix semiconductor chips downward along the first direction, which are attached onto the mount tape by being disposed to be adjacent to the mount tape and the target semiconductor chip.

According to some implementations of the present disclosure, there is provided a chip ejecting apparatus, comprising a table receiving a mount tape and semiconductor chips attached onto the mount tape; a body provided inside the table, disposed below the mount tape and formed with a plurality of vacuum holes; and an ejecting bar provided in the body and driven to ascend and descend along a first direction, wherein the ejecting bar is driven upward along the first direction to push up a target semiconductor chip for pickup among the semiconductor chips attached onto the mount tape so that a collet device adsorbs and picks up the target semiconductor chip, and the body sucks the air through the plurality of vacuum holes to adsorb and fix semiconductor chips downward along the first direction, which are disposed to be adjacent to the mount tape and the target semiconductor chip.

According to some implementations of the present disclosure, there is provided a semiconductor device manufacturing method comprising, forming a semiconductor chip by cutting a wafer; pushing up a target semiconductor chip for pickup among the semiconductor chips provided to a chip ejecting apparatus in a state that they are attached onto a mount tape, along a first direction so that a collet device picks up the target semiconductor chip; and attaching the semiconductor chip onto a substrate, wherein the target semiconductor chip is pushed up along the first direction so that the collet device picks up the target semiconductor chip in a state that the semiconductor chips disposed to be adjacent to the mount tape and the target semiconductor chip are adsorbed and fixed downward along the first direction.

In the chip ejecting apparatus and the method for fabricating a semiconductor device using the same according to some implementations, a semiconductor chip may be pushed up through an ejecting bar in a state of a face-to-face contact with a semiconductor chip attached to a mount tape, so that stress that can be applied to the semiconductor chip may be minimized, whereby damage to the semiconductor chip may be suppressed. Since the semiconductor chip may be easily separated from the mount tape by vacuum holes and an edge groove provided to partially include the vacuum holes, pickup efficiency of the semiconductor chip may be enhanced.

The effects according to the implementations of the present disclosure are not limited to those mentioned above, and more various effects are included in the following description of the present disclosure.

### BRIEF DESCRIPTION OF THE DRAWINGS

The above and other aspects and features of the present disclosure will become more apparent by describing in detail exemplary implementation thereof with reference to the attached drawings, in which:

FIGS. 1 and 2 are schematic perspective views illustrating a chip ejecting apparatus according to some implementations of the present disclosure:

FIG. 3 is a schematic cross-sectional view illustrating a chip ejecting apparatus according to some implementations:

FIG. 4 is a schematic view illustrating driving of an ejecting bar of a chip ejecting apparatus according to some implementations of the present disclosure;

FIGS. 5 to 8 are schematic cross-sectional views illustrating a process of picking up a semiconductor chip to a collet device by separating the semiconductor chip from the mount tape through the chip ejecting apparatus according to some implementations of the present disclosure:

FIGS. 9 to 11 are schematic cross-sectional views illustrating an ejecting bar of a chip ejecting apparatus according to some implementations of the present disclosure:

FIGS. 12 to 15 are schematic cross-sectional views illustrating an ejecting bar of a chip ejecting apparatus according to some implementations of the present disclosure;

FIG. 16 is a schematic cross-sectional view illustrating a chip ejecting apparatus according to some implementations of the present disclosure;

FIG. 17 is a schematic view illustrating driving of a body of a chip ejecting apparatus according to some implementations of the present disclosure; and

FIG. 18 is a flow chart illustrating a method for fabricating a semiconductor device using a chip ejecting apparatus according to some implementations of the present disclosure.

### DETAILED DESCRIPTION

Implementations of the present disclosure will hereinafter be described in detail with reference to the accompanying drawings. The advantages and features of the present disclosure, and the methods to achieve them, will become clear by referring to the implementations detailed with the accompanying drawings. However, the present disclosure is not limited to the implementations disclosed below but can be implemented in various different forms. These implementations are provided to make the disclosure of the present disclosure complete and to fully inform those skilled in the art to which the present disclosure pertains. The present disclosure is defined by the scope of the claims. Throughout the specification, the same reference numerals denote the same components.

Terms used in this specification are for the purpose of describing particular implementations only and are not intended to be limiting of the present disclosure. In this specification, singular forms are intended to include plural forms as well, unless the context clearly indicates otherwise. The terms “comprises” and/or “comprising,” when used in this specification, specify the presence of stated features, steps, operations, elements, and/or components, but do not preclude the presence or addition of one or more other features, steps, operations, elements, components, and/or groups thereof.

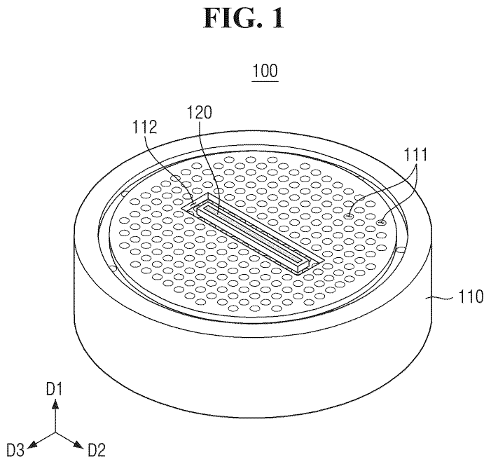

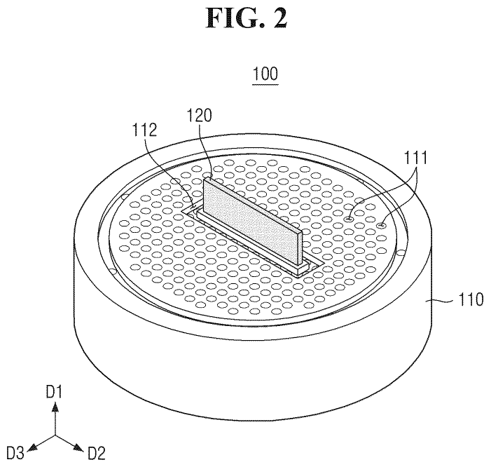

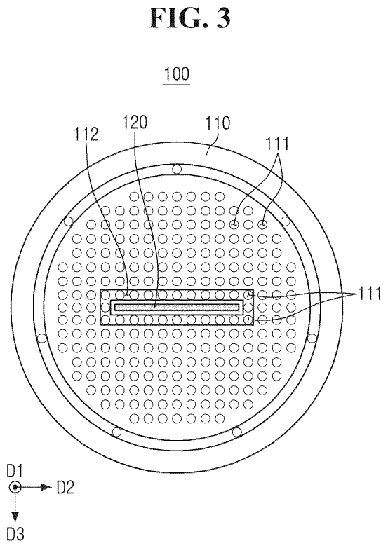

FIGS. 1 and 2 are schematic perspective views illustrating a chip ejecting apparatus according to some implementations of the present disclosure. FIG. 3 is a schematic cross-sectional view illustrating a chip ejecting apparatus according to some implementations.

Referring to FIGS. 1 to 3, a chip ejecting apparatus 100 according to some implementations of the present disclosure includes a body 110 and an ejecting bar 120.

In this case, a first direction D1 is a height direction, and is a direction perpendicular to a plane configured by a second direction D2 and a third direction D3. The first direction D1 may be an up and down direction. The second direction D2 and the third direction D3 may constitute a plane in a horizontal direction. The second direction D2 may be a front-rear direction, and the third direction D3 may be a left-right direction. Alternatively, the second direction D2 may be a left-right direction, and the third direction D3 may be a front-rear direction.

The body 110 may have a cylindrical shape, but the present disclosure is not limited thereto. For example, the body 110 may be provided in a column shape having a polygonal cross-section along the second direction D2 and the third direction D3, such as a square, a hexagon or an octagon. The body 110 may be configured in a shape in which a plurality of vacuum holes 111 are formed.

The plurality of vacuum holes 111 may have a shape passing through the body 110 along the first direction D1.

The plurality of vacuum holes 111 may have a shape of a suction pipe. The plurality of vacuum holes 111 having a shape of a suction pipe may be connected to a pump. The plurality of vacuum holes 111 may be connected to a pump provided outside the body 110. The pump may be operated under the control of a controller. The pump may suck the air through the plurality of vacuum holes 111 at a pressure preset by the controller to adsorb a mount tape 2 and semiconductor chips C attached onto the mount tape 2.

The pump connected to the plurality of vacuum holes 111 may be also provided as a plurality of pumps. Alternatively, only the vacuum hole 111 may be provided as a plurality of vacuum holes to have a shape branched from one pump. When a plurality of pumps are provided to correspond to the plurality of vacuum holes 111, the same number of vacuum holes 111 and pumps may be provided.

A valve that can be opened and closed may be provided between the plurality of vacuum holes 111 and the pump. The valve may be disposed inside or outside the body 110. The valve may be operated under the control of the controller. When the valve is opened, the air may be sucked through the plurality of vacuum holes 111, whereby the mount tape 2 and the semiconductor chips C attached onto the mount tape 2 may be adsorbed.

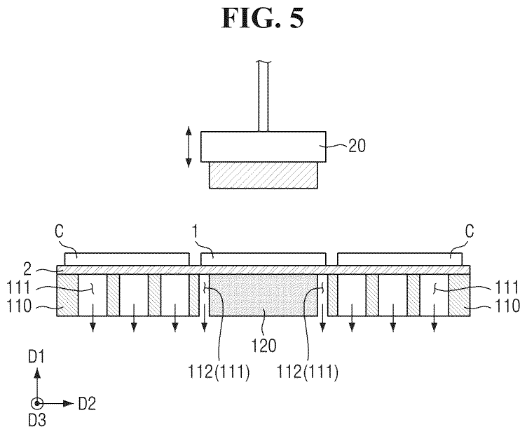

The pump and the valve, which are connected to the plurality of vacuum holes 111, are operated under the control of the controller. For example, when the controller intends to pick up a target semiconductor chip 1 for pickup through a collet device 20 (illustrated in FIG. 5), the controller may operate the pump and at the same time open the valve, and when the body 110 moves in the second direction D2 or the third direction D3 to pick up another semiconductor chip C, the controller may stop the operation of the pump and at the same time close the valve.

The plurality of vacuum holes 111 may be arranged in a radial or lattice shape. The plurality of vacuum holes 111 may constitute a shape arranged in a radial or lattice shape on an upper surface of the body 110.

Through the plurality of vacuum holes 111, the body 110 sucks the air downward along the first direction D1 to adsorb and fix the semiconductor chips C downward along the first direction D1, which are disposed to be adjacent to the mount tape 2 (illustrated in FIG. 5) and the target semiconductor chip 1 for pickup and attached onto the mount tape 2.

The body 110 includes an edge groove 112 formed on the upper surface along the first direction D1.

The edge groove 112 may have a shape surrounding the ejecting bar 120. The edge groove 112 may have the same shape as that of the ejecting bar 120. For example, when a cross-section of the ejecting bar 120 along the second direction D2 and the third direction D3 is formed in a rectangular shape, the edge groove 112 may be also formed in a rectangular shape surrounding the ejecting bar 120.

The edge groove 112 includes a portion of the plurality of vacuum holes 111.

Through this, the ejecting bar 120 may push up the target semiconductor chip 1 while the edge groove 112 adsorbs an edge region of the target semiconductor chip 1 for pickup during a pickup process of the semiconductor chip C, thereby easily separating the target semiconductor chip 1 from the mount tape 2.

That is, a part of the mount tape 2, to which the edge region of the pickup target semiconductor chip 1 is attached, is maintained to be adsorbed downward along the first direction D1 by the vacuum holes 111 included in the edge groove 112. In this state, the ejecting bar 120 continuously pushes up the target semiconductor chip 1, so that the target semiconductor chip 1 may be easily separated from the mount tape 2.

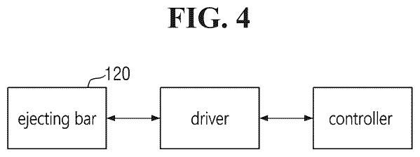

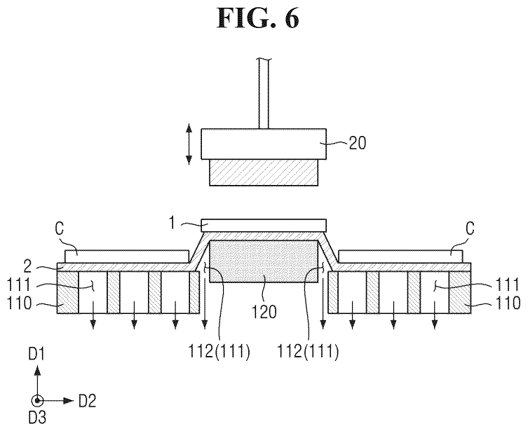

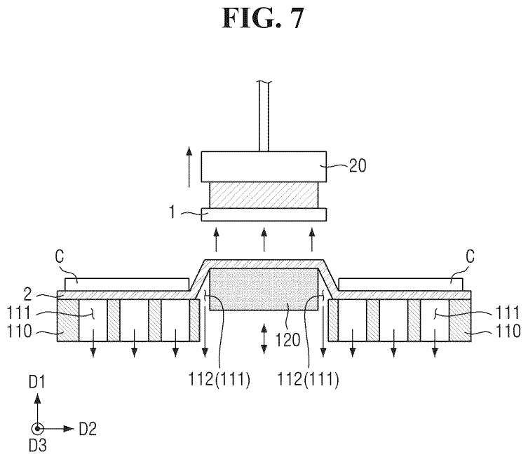

FIG. 4 is a schematic view illustrating driving of an ejecting bar of a chip ejecting apparatus according to some implementations of the present disclosure. FIGS. 5 to 8 are schematic cross-sectional views illustrating a process of picking up a semiconductor chip to a collet device by separating the semiconductor chip from the mount tape through the chip ejecting apparatus according to some implementations of the present disclosure.

Referring to FIGS. 1 to 8, the ejecting bar 120 may be provided in the body 110. The ejecting bar 120 may be driven to ascend and descend along the first direction D1 from the body 110. The ejecting bar 120 may be disposed at a central portion of the body 110 along the second direction D2 and the third direction D3.

The ejecting bar 120 may be driven upward along the first direction D1 from the body 110 to push up the target semiconductor chip 1 attached onto the mount tape 2 so that the collet device 20 may adsorb and pick up the target semiconductor chip 1.

The ejecting bar 120 may have a rectangular block shape corresponding to the semiconductor chip C. The ejecting bar 120 may have cross-sections along the second and third directions D2 and D3 in a rectangular shape corresponding to the semiconductor chip C.

Therefore, the ejecting bar 120 may push up the target semiconductor chip 1 for pickup in a state of a face-to-face contact with the semiconductor chip C attached to the mount tape 2, so as to minimize the stress that can be applied to the semiconductor chip C, thereby suppressing damage to the semiconductor chip C.

The ejecting bar 120 may be provided in a shape in which an area of a cross-section along the second direction D2 and the third direction D3 is smaller than an area of the semiconductor chip C. As an area of an upper surface of the ejecting bar 120 is provided in a shape smaller than the area of the semiconductor chip C, the ejecting bar 120 interworks with the vacuum holes 111 included in the edge groove 112 so that the semiconductor chip C may be easily separated from the mount tape 2 during the pickup process of the semiconductor chip C, thereby enhancing pickup efficiency of the semiconductor chip C, but the present disclosure is not limited thereto. The size of the ejecting bar 120 may be variously provided to correspond to the size of the semiconductor chip C.

In addition, the semiconductor chip C to be picked up in a die (chip) pickup process to which the chip ejecting apparatus 100 according to some implementations of the present disclosure is applied may have a short side of 1.5 mm or less.

That is, the chip ejecting apparatus 100 according to some implementations of the present disclosure has a technical feature in that it is applied to the pickup process of the miniaturized and thinned semiconductor chip C with a short side of 1.5 mm or less to minimize the stress that can be applied to the semiconductor chip C, thereby suppressing damage such as crack in the semiconductor chip C.

Meanwhile, the chip ejecting apparatus 100 according to some implementations of the present disclosure may further include a driver for driving the ejecting bar 120 to ascend and descend along the first direction D1 and a controller for controlling the driver. The driver may be provided in the form of a motor or a cylinder connected to the motor, but the present disclosure is not limited thereto.

For example, when the controller intends to pick up the target semiconductor chip 1 for pickup through the collet device 20, the controller may operate the driver to ascend the ejecting bar 120, and when the body 110 moves in the second direction D2 or the third direction D3 for pickup of other semiconductor chip C after completing the pickup of the target semiconductor chip 1, the controller may descend the ejecting bar 120 by operating the driver.

In addition, the controller may control the speed, force or height of the ejecting bar 120 ascending along the first direction D1 through the operation of the driver, and this configuration of the driver and the controller may be synchronized with a pusher among facilities applied to the die (chip) attaching process.

The ejecting bar 120 may be provided in an antistatic-processed state.

Therefore, as the ejecting bar 120 ascends during the pickup process of the semiconductor chip C, a cell included in the semiconductor chip C may be prevented from being damaged by static electricity. For example, the antistatic-processed state of the ejecting bar 120 may dissipate static electricity in a specific region (upper portion or upper surface) of the ejecting bar 120, which may constitute a face-to-face contact with the semiconductor chip C attached onto the mount tape 2, but the present disclosure is not limited thereto.

Referring to FIG. 5, the body 110 of the chip ejecting apparatus 100 according to some implementations of the present disclosure may move in the second direction D2 or the third direction D3 such that the ejecting bar 120 is positioned vertically below the target semiconductor chip 1 for pickup along the first direction D1, whereby the body 110 may be in close contact with a lower surface of the mount tape 2. In this case, the collet device 20 may move in the first direction D1, the second direction D2 or the third direction D3 to be positioned vertically above the target semiconductor chip 1 for pickup along the first direction D1.

Referring to FIGS. 5 to 7, the mount tape 2 and the semiconductor chips C attached onto the mount tape 2 may be adsorbed through the plurality of vacuum holes 111. The ejecting bar 120 may ascend in the first direction D1 by the operation of the driver through control of the controller. The ejecting bar 120 may push up the target semiconductor chip 1 for pickup. A suction action through the plurality of vacuum holes 111 may be maintained. While the ejecting bar 120 pushes up the target semiconductor chip 1, the suction action through the plurality of vacuum holes 111 may be maintained so that the semiconductor chips C disposed to be adjacent to the mount tape 2 and the target semiconductor chip 1 and attached onto the mount tape 2 may be adsorbed and fixed downward along the first direction D1.

The collet device 20 may descend in the first direction D1 to adsorb and pick up the target semiconductor chip 1 for pickup. The suction action of the vacuum holes 111 included in the edge groove 112 may be continuously maintained so that the target semiconductor chip 1 may be easily separated from the mount tape 2.

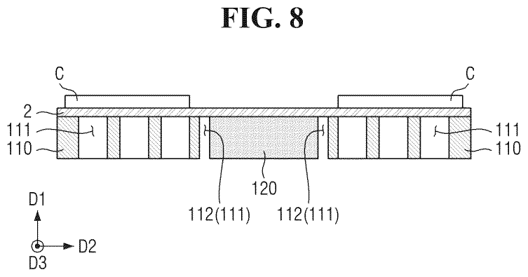

Referring to FIG. 8, after the pickup of the target semiconductor chip 1 is completed, the ejecting bar 120 may descend in the first direction D1 for pickup of other semiconductor chip C by the operation of the driver through the control of the controller. The ejecting bar 120 may be positioned below the upper surface of the body 110 along the first direction D1 so as not to interfere with the mount tape 2 and the semiconductor chip C attached onto the mount tape 2 when the body 110 moves, thereby preventing damage or breakage of the semiconductor chip C. The controller may stop the operation of the pump and at the same time close the valve, thereby stopping the suction action of the plurality of vacuum holes 111. The body 110 may move in the second direction D2 or the third direction D3 for pickup of other semiconductor chip C.

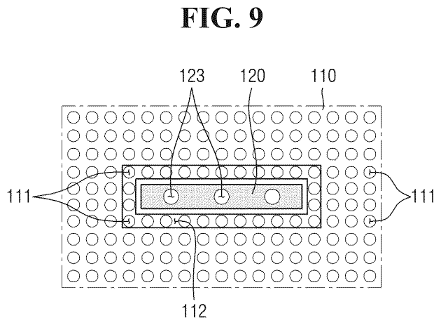

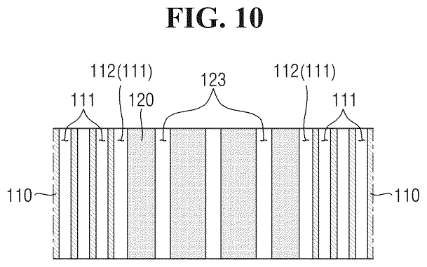

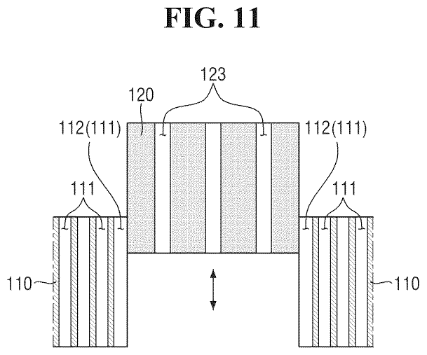

FIGS. 9 to 11 are schematic cross-sectional views illustrating an ejecting bar of a chip ejecting apparatus according to some implementations of the present disclosure.

Referring to FIGS. 9 to 11, the ejecting bar 120 may be provided in a shape in which one or more exhaust holes 123 are formed.

The exhaust hole 123 may pass through the ejecting bar 120 along the first direction D1. The exhaust hole 123 may have a shape of an exhaust pipe. The exhaust hole 123 having a shape of an exhaust pipe may be connected to the pump. The exhaust hole 123 may be connected to the pump provided outside the ejecting bar 120 (or outside the body 110). The pump may be operated under the control of the controller. The pump may exhaust the air through one or more exhaust holes 123 at a pressure preset by the controller to discharge the air toward the mount tape 2 and the semiconductor chips C attached onto the mount tape 2.

The discharge of the air to an upper side in the first direction D1 through the exhaust hole 123 acts together with the ejecting bar 120 that pushes up the target semiconductor chip 1 for pickup, which is attached to the mount tape 2, whereby efficiency in pickup of the semiconductor chip C may be enhanced.

The pump connected to one or more exhaust holes 123 may be also provided as one or more pumps. Alternatively, only the exhaust hole 123 may be provided as a plurality of exhaust holes to have a shape branched from one pump. When a plurality of pumps are provided to correspond to the plurality of exhaust holes 123, the same number of exhaust holes 123 and pumps may be provided.

A valve that can be opened and closed may be provided between the exhaust hole 123 and the pump. The valve may be disposed inside or outside the ejecting bar 120 (or outside the body 110). The valve may be operated under the control of the controller. When the valve is opened, the air may be discharged through one or more exhaust holes 123.

The pump and the valve, which are connected with the exhaust hole 123, are operated under the control of the controller. For example, when the controller intends to pick up the target semiconductor chip 1 for pickup through the collet device 20, the controller may operate the pump and at the same time open the valve, and when the body 110 moves in the second direction D2 or the third direction D3 in a state that the ejecting bar 120 descends in the first direction D1 for pickup of other semiconductor chip C, the controller may stop the operation of the pump and at the same time close the valve.

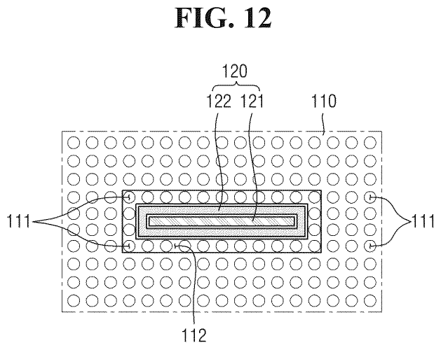

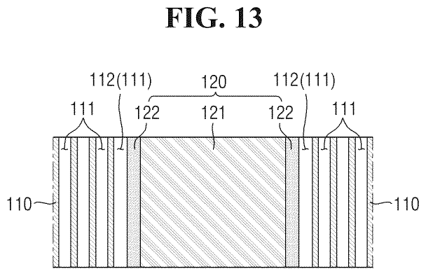

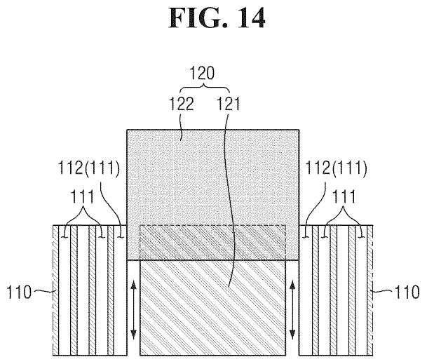

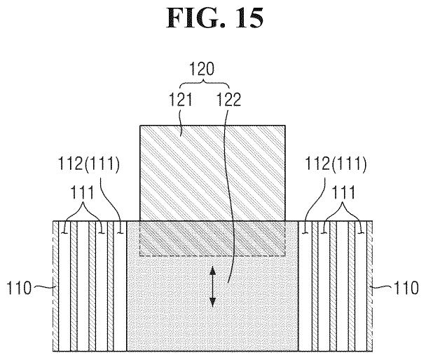

FIGS. 12 to 15 are schematic cross-sectional views illustrating an ejecting bar of a chip ejecting apparatus according to some implementations of the present disclosure.

Referring to FIGS. 12 to 15, the ejecting bar 120 includes a first bar 121 disposed at a central portion along the second direction D2 and the third direction D3. The ejecting bar 120 may have a shape that includes a second bar 122 surrounding the first bar 121, disposed outside the first bar 121 and spaced apart from the first bar 121 along the second direction D2 and the third direction D3.

The first bar 121 and the second bar 122 may have a rectangular block shape corresponding to the semiconductor chip C. Cross-sections of the first bar 121 and the second bar 122 along the second and third directions D2 and D3 may be provided in a rectangular shape corresponding to the semiconductor chip C.

Therefore, the first bar 121 and the second bar 122 may push up the target semiconductor chip 1 for pickup in a state of a face-to-face contact with the semiconductor chip C attached to the mount tape 2, so as to minimize the stress that can be applied to the semiconductor chip C, thereby suppressing damage to the semiconductor chip C.

The first bar 121 and the second bar 122 may ascend and descend independently or simultaneously along the first direction D1 by corresponding to the area of the target semiconductor chip 1. In this case, a short side and a long side of the cross-section of the first bar 121 along the second and third directions D2 and D3 may be shorter than a short side and a long side, respectively, of the cross-section of the second bar along the second and third directions D2 and D3. Therefore, the first bar 121 and the second bar 122 may ascend and descend independently or simultaneously based on the area of the target semiconductor chip 1.

Meanwhile, the chip ejecting apparatus 100 according to some implementations of the present disclosure may further include a driver for driving the first bar 121 and the second bar 122 respectively or simultaneously to ascend and descend along the first direction D1, and a controller for controlling the driver. The driver may be provided in the form of a motor or a cylinder connected to the motor, but the present disclosure is not limited thereto.

For example, when the controller intends to pick up the target semiconductor chip 1 for pickup through the collet device 20, the controller may ascend or descend the first bar 121 and the second bar 122 respectively or simultaneously by operating the driver to correspond to the size of the target semiconductor chip 1. When the body 110 moves in the second direction D2 or the third direction D3 for pickup of other semiconductor chip C after completing the pickup of the target semiconductor chip 1, the controller may descend both the first bar 121 and the second bar 122 by operating the driver.

In addition, the controller may control the speed, force or height at which the first bar 121 and the second bar 122 ascend along the first direction D1, respectively, through the operation of the driver.

The first bar 121 and the second bar 122 may be provided in a shape in which one or more exhaust holes 123 are formed.

The exhaust hole 123 may pass through the first bar 121 and the second bar 122 respectively along the first direction D1. The exhaust hole 123 of each of the first bar 121 and the second bar 122 may have a shape of an exhaust pipe. The exhaust hole 123 having a shape of an exhaust pipe may be connected to the pump. The exhaust hole 123 of each of the first bar 121 and the second bar 122 may be connected to the pump provided outside the first bar 121 and the second bar 122 (or outside the body 110). The pump may be operated under the control of the controller. The pump may exhaust the air through one or more exhaust holes 123 at a pressure preset by the controller to discharge the air toward the mount tape 2 and the semiconductor chips C attached onto the mount tape 2.

The discharge of the air to an upper side in the first direction D1 through the exhaust hole 123 acts together with the first bar 121 or the second bar 122, which pushes the target semiconductor chip 1 attached to the mount tape 2, whereby efficiency in pickup of the semiconductor chip C may be enhanced.

The pump connected to one or more exhaust holes 123 may be also provided as one or more pumps. Alternatively, only the exhaust hole 123 may be provided as a plurality of exhaust holes to have a shape branched from one pump. When a plurality of pumps are provided to correspond to the plurality of exhaust holes 123, the same number of exhaust holes 123 and pumps may be provided.

A valve that can be opened and closed may be provided between the exhaust hole 123 of each of the first bar 121 and the second bar 122 and the pump. The valve may be disposed inside or outside the first bar 121 and the second bar 122 (or outside the body 110). The valve may be operated under the control of the controller. When the valve is opened, the air may be discharged through one or more exhaust holes 123.

The pump and the valve, which are connected with the exhaust hole 123, are operated under the control of the controller. For example, when the controller intends to pick up the target semiconductor chip 1 for pickup through the collet device 20, the controller may operate the pump and at the same time open the valve, and when the body 110 moves in the second direction D2 or the third direction D3 in a state that both the first bar 121 and the second bar 122 descend in the first direction D1 for pickup of other semiconductor chip C, the controller may stop the operation of the pump and at the same time close the valve.

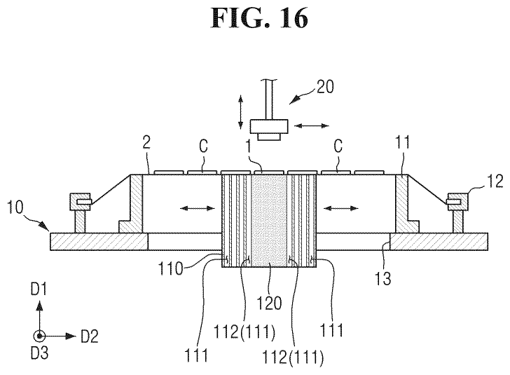

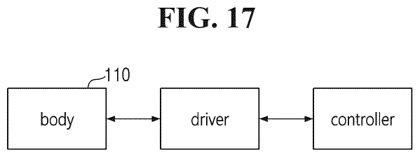

FIG. 16 is a schematic cross-sectional view illustrating a chip ejecting apparatus according to some implementations of the present disclosure. FIG. 17 is a schematic view illustrating driving of a body of a chip ejecting apparatus according to some implementations of the present disclosure.

Referring to FIGS. 16 and 17, the chip ejecting apparatus 100 according to some implementations of the present disclosure may have a shape in which it includes a table 10.

The table 10 receives the mount tape 2 and the semiconductor chips C divided into a large number of chips from a wafer through a dicing process.

The table 10 includes a frame 12. The mount tape 2 to which the plurality of semiconductor chips C are attached may be fixed to the frame 12. For example, the frame 12 may have a circular shape along the second direction D2 and the third direction D3. The circular frame 12 may fix the mount tape 2 along an edge of the mount tape 2.

The table 10 may further include a support 11. The support 11 may support the vicinity of the edge of the mount tape 2. The frame 12 of the table 10 may descend along the first direction D1. Since the vicinity of the edge of the mount tape 2 may be supported by the support 11, the mount tape 2 may be expanded outward along the second direction D2 and the third direction D3 in accordance with descending of the frame 12. The expanded mount tape 2 may allow the plurality of semiconductor chips C to be more easily separated from the mount tape 2.

The table 10 includes a space 13 formed inside.

The body 110 may be provided in the space 13 formed inside the table 10. The body 110 may be disposed below the mount tape 2 along the first direction D1. The upper surface of the body 110 may have a shape disposed to face the lower surface of the mount tape 2. The body 110 may move along the second direction D2 or the third direction D3 in the space 13 inside the table 10.

Meanwhile, the chip ejecting apparatus 100 according to some implementations of the present disclosure may have a shape in which it further includes a driver for moving the body 110 along the second direction D2 or the third direction D3 in the space 13 of the table 10 and a controller for controlling the driver. The driver may be provided in the form of a motor or a moving guide rail connected to the motor, but the present disclosure is not limited thereto.

For example, when the controller is about to pick up the target semiconductor chip 1 for pickup through the collet device 20, the controller may move the body 110 in the second direction D2 or the third direction D3 by operating the driver so that the ejecting bar 120 is positioned vertically below the target semiconductor chip 1 for pickup along the first direction D1.

In this case, the collet device 20 may move in the first direction D1, the second direction D2 or the third direction D3 to be positioned vertically above the target semiconductor chip 1 for pickup along the first direction D1.

Also, when the pickup of the target semiconductor chip 1 is completed, the controller may move the body 110 in the second direction D2 or the third direction D3 for pickup of other semiconductor chip C. In this case, the ejecting bar 120 may descend along the first direction D1 and be positioned inside the body 110.

The controller may control the speed, force or distance, at which the body 110 moves along the second direction D2 or the third direction D3, through the operation of the driver.

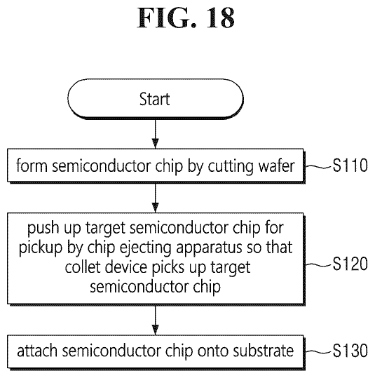

FIG. 18 is a flow chart illustrating a method for fabricating a semiconductor device using a chip ejecting apparatus according to some implementations of the present disclosure.

Referring to FIGS. 5 to 8 and 18, a plurality of semiconductor chips C spaced apart from each other may be formed by cutting a wafer through a dicing process (S110).

The plurality of semiconductor chips C may be provided to the chip ejecting apparatus 100 in a state that they are attached to the mount tape 2. The target semiconductor chip 1 for pickup among the plurality of semiconductor chips C may be pushed up along the first direction D1 through the ejecting bar 120 of the chip ejecting apparatus 110. Then, the collet device 20 may pick up the target semiconductor chip 1 (S120).

At this time, through a plurality of vacuum holes 111 and an edge groove 112 including some of the plurality of vacuum holes 111, the target semiconductor chip 1 may be pushed up along the first direction D1 so that the collet device 20 may pick up the target semiconductor chip 1 in a state that the semiconductor chips C disposed to be adjacent to the mount tape 2 and the target semiconductor chip 1 are adsorbed and fixed downward along the first direction D1.

Subsequently, the collet device 20 may move onto a separate stage where the substrate is positioned, and may descend to attach the semiconductor chip C onto the substrate (S130).

In this case, the substrate may be any one of a printed circuit board (PCB), an interposer, another semiconductor chip and a semiconductor package, but the present disclosure is not limited thereto.

Subsequently, the semiconductor chip C may be bonded to the substrate, and then may be electrically connected to the substrate through a wire or a through silicon via (TSV). Then, the semiconductor device or the semiconductor package may be fabricated by forming a mold layer to cover the semiconductor chip C.

As described above, in the chip ejecting apparatus and the method for fabricating a semiconductor device using the same, the semiconductor chip C may be pushed up through the ejecting bar 120 in a state of a face-to-face contact with the semiconductor chip C attached to the mount tape, so that stress that can be applied to the semiconductor chip C may be minimized, whereby damage to the semiconductor chip C may be suppressed. Since the semiconductor chip C may be easily separated from the mount tape 2 by the vacuum holes 111 and the edge groove 112 provided to partially include the vacuum holes 111, pickup efficiency of the semiconductor chip C may be enhanced.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the implementations of the present disclosure have been described with reference to the accompanying drawings, it will be understood by those skilled in the art that the present disclosure can be implemented in other specific forms without changing the technical spirit or essential features thereof. Therefore, the implementations described above should be considered in all respects as illustrative and not restrictive.

What is claimed is:

1. A chip ejecting apparatus comprising:
a body formed with a plurality of vacuum holes; and
an ejecting bar provided in the body and driven to ascend and descend along a first direction,
wherein the ejecting bar is configured to be driven upward along the first direction to push up a target semiconductor chip attached onto a mount tape so that a collet device adsorbs and picks up the target semiconductor chip, and
the body is configured to suck air through the plurality of vacuum holes to adsorb and fix a plurality of semiconductor chips downward along the first direction, wherein the plurality of semiconductor chips are attached onto the mount tape by being disposed to be adjacent to the mount tape and the target semiconductor chip.

2. The chip ejecting apparatus of claim 1, wherein the body has a cylindrical shape, and
the plurality of vacuum holes are arranged in a radial or lattice pattern in the body, wherein each vacuum hole of the plurality of vacuum holes has a shape of a suction pipe passing through the body along the first direction.

3. The chip ejecting apparatus of claim 1, wherein the body includes an edge groove formed on an upper surface along the first direction, and
the edge groove has a shape surrounding the ejecting bar.

4. The chip ejecting apparatus of claim 3, wherein the edge groove includes one or more vacuum holes of the plurality of vacuum holes.

5. The chip ejecting apparatus of claim 1, further comprising:
a driver configured to drive the ejecting bar to ascend and descend along the first direction; and
a controller configured to control the driver.

6. The chip ejecting apparatus of claim 1, wherein the ejecting bar is disposed at a central portion of the body along a second direction and a third direction.

7. The chip ejecting apparatus of claim 1, wherein the ejecting bar has a rectangular block shape corresponding to the semiconductor chip.

8. The chip ejecting apparatus of claim 1, wherein the ejecting bar is provided in an antistatic-processed state.

9. The chip ejecting apparatus of claim 1, wherein an area of a cross-section along a second direction and a third direction of the ejecting bar is smaller than an area of the semiconductor chip.

10. The chip ejecting apparatus of claim 1, wherein the ejecting bar is formed with one or more exhaust holes.

11. The chip ejecting apparatus of claim 10, wherein each exhaust hole of the one or more exhaust holes has a shape of an exhaust pipe passing through the ejecting bar along the first direction.

12. The chip ejecting apparatus of claim 1, wherein the ejecting bar includes:
a first bar disposed at a central portion of the body along a second direction and a third direction; and
a second bar surrounding the first bar, disposed outside the first bar and spaced apart from the first bar along the second direction and the third direction.

13. The chip ejecting apparatus of claim 12, wherein the first bar and the second bar are configured to, based on an area of the target semiconductor chip, ascend and descend independently or simultaneously along the first direction.

14. The chip ejecting apparatus of claim 12, wherein the first bar and the second bar are formed with one or more exhaust holes, and
each exhaust hole of the one or more exhaust holes has a shape of an exhaust pipe passing through each of the first bar and the second bar along the first direction.

15. The chip ejecting apparatus of claim 1, wherein the semiconductor chip has a short side of 1.5 mm or less.

16. A chip ejecting apparatus comprising:
a table configured to receive a mount tape and a plurality of semiconductor chips attached onto the mount tape;
a body provided inside the table, disposed below the mount tape and formed with a plurality of vacuum holes; and
an ejecting bar provided in the body and configured to be driven to ascend and descend along a first direction,
wherein the ejecting bar is configured to be driven upward along the first direction to push up a target semiconductor chip for pickup among the plurality of semiconductor chips attached onto the mount tape so that a collet device adsorbs and picks up the target semiconductor chip, and
the body is configured to suck air through the plurality of vacuum holes to adsorb and fix semiconductor chips downward along the first direction, wherein the plurality of semiconductor chips are disposed to be adjacent to the mount tape and the target semiconductor chip.

17. The chip ejecting apparatus of claim 16, wherein the body is configured to move along a second direction or a third direction inside the table.

18. The chip ejecting apparatus of claim 17, further comprising:
a driver configured to move the body along the second direction or the third direction; and
a controller configured to control the driver.

19. The chip ejecting apparatus of claim 16, wherein the body includes an edge groove formed on an upper surface along the first direction, wherein the edge groove includes one or more vacuum holes of the plurality of vacuum holes, and the edge groove surrounds the ejecting bar, and
wherein the ejecting bar has a rectangular block shape corresponding to the semiconductor chip, and
wherein the ejecting bar is provided in an antistatic-processed state.

20. A method for fabricating a semiconductor device, the method comprising:
forming a semiconductor chip by cutting a wafer;
pushing up a target semiconductor chip along a first direction for pickup by a collet device, wherein the target semiconductor chip is among a plurality of semiconductor chips provided to a chip ejecting apparatus, wherein the plurality of semiconductor chips are attached onto a mount tape; and
attaching the semiconductor chip onto a substrate,
wherein the plurality of semiconductor chips are disposed to be adjacent to the mount tape and the target semiconductor chip, and wherein the plurality of semiconductor chips are adsorbed and fixed downward along the first direction.
